(19) United States
(12) Patent Application Publication
(10) Pub. No.: US 2013/0100617 A1
(43) Pub. Date: Apr. 25, 2013

(54) Connector and Wireless Modem

(71) Applicant: Huawei Device Co., Ltd., Shenzhen (CN)

(72) Inventor: Shuai Zhao, Shenzhen (CN)

(73) Assignee: Huawei Device Co., Ltd., Shenzhen (CN)

(21) Appl. No.: 13/711,068

(22) Filed: Dec. 11, 2012

Related U.S. Application Data
(63) Continuation of application No. PCT/CN2012/071642, filed on Feb. 25, 2012.

(30) Foreign Application Priority Data
Feb. 25, 2011 (CN) 201120049040.7

(51) Int. Cl. H05K 5/02

(52) U.S. Cl. CPC H05K 5/0278
USPC 361/737

(57) ABSTRACT

The present invention discloses a connector and a wireless modem, and the present invention relates to the field of electronic products. The connector includes a printed circuit board (PCB). One surface of the PCB is disposed with USB pins, and the other surface is disposed with smart card pins. A frame is disposed outside the PCB, and the frame is configured to bear the PCB. The frame and the USB pins form a USB connector. The frame and the PCB surface disposed with the smart card pins form a cavity, and a smart card is inserted into the cavity to form a smart card connector. The wireless modem includes the connector. As a result, a data card product adopting the present invention may effectively economize its volume, and materials of two card holders may be generally reduced. Thus, the cost of a data card product may be lowered.

### CROSS-REFERENCE TO RELATED APPLICATIONS

This application is a continuation of International Application No. PCT/CN2012/071642, filed on Feb. 25, 2012, which claims priority to Chinese Patent Application No. 201120049040.7, filed on Feb. 25, 2011, both of which are hereby incorporated by reference in their entireties.

### STATEMENT REGARDING FEDERALLY SPONSORED RESEARCH OR DEVELOPMENT

Not applicable.

### REFERENCE TO A MICROFICHE APPENDIX

Not applicable.

### TECHNICAL FIELD

The present invention relates to the field of electronic products, and in particular, to a connector and a wireless modem.

### BACKGROUND

At present, various wireless modems (e.g., data cards) exist on the market, and the general development trend thereof is the requirement of small size and powerful function, that is, the requirement of continuously improving the integration level. However, various connectors (e.g., card holders), such as universal serial bus (USB) connectors, subscriber identity module (SIM) card connectors and secure digital memory (SD) card connectors, that match with data cards, commonly exist in the form of separated devices. Therefore, such connectors usually take most of the space of data card products, which affects the miniaturization progress of the data card products. Though, a two-in-one device which integrates a SIM card holder and an SD card holder exists on the market, a high cost and a big size of a data card are adverse to the miniaturization trend of a data card product.

### SUMMARY

Accordingly, the present invention provides a connector and a wireless modem. The technical solutions are as follows:

A connector is provided that includes a printed circuit board (PCB).One surface of the PCB is disposed with USB pins, and the other surface is disposed with smart card pins. A frame is disposed outside the PCB. The frame is configured to bear the PCB, and the frame and the USB pins form a USB connector. The frame and the PCB surface disposed with the smart card pins form a cavity, and a smart card is inserted into the cavity, so as to form a smart card connector.

The present invention further provides a wireless modem that includes a USB connector. The connector includes a PCB. One surface of the PCB is disposed with USB pins, and the other surface is disposed with smart card pins. A frame is disposed outside the PCB. The frame is configured to bear the PCB, and the frame and the USB pins form the USB connector. The frame and the PCB surface disposed with the smart card pins form a cavity, and a smart card is inserted into the cavity, so as to form a smart card connector.

Advantages of the technical solutions provided by the present invention are that: comparing the conventional art with embodiments of the present invention, by disposing the USB pins and the smart card pins on both surfaces of the PCB, respectively, and configuring the frame outside the PCB, a structure of the USB connector and the smart card connector is formed; the outline of the structure is equivalent to the USB connector of the conventional art, therefore no extra space is occupied; and the present invention has a simple structure, which is beneficial to the miniaturization of a data card product and convenient for repair and maintenance, and has a low cost.

### BRIEF DESCRIPTION OF THE DRAWINGS

To illustrate the technical solutions in the embodiments of the present invention more clearly, the following briefly describes the accompanying drawings required for describing the embodiments. Apparently, the accompanying drawings in the following description merely show some embodiments of the present invention, and persons of ordinary skill in the art can derive other drawings from the accompanying drawings without creative efforts.

FIG. 1 is an overall structural diagram of a connector described in Embodiment 1 of the present invention;

FIG. 2 is a structural diagram of a PCB described in an embodiment of the present invention;

FIG. 3 is a structural diagram of an SD card described in an embodiment of the present invention;

FIG. 3a is a front view of the SD card described in FIG. 3;

FIG. 3b is a side view of FIG. 3a;

FIG. 4 is a structural diagram of a half-head frame described in Embodiment 1 of the present invention;

FIG. 4a is an A-direction view of a cavity shown in FIG. 4;

FIG. 5 is an overall structural diagram of a connector described in Embodiment 2 of the present invention; and

FIG. 6 is a structural diagram of a full-head frame disposed with a PCB described in Embodiment 2 of the present invention.

In the accompanying drawings, components represented by reference numerals are listed as follows: 1 PCB, 2 SD card, 3 frame, 3.1 bottom surface, 3.2 first opening, 3.3 sidewall, 3.4 cavity, 3.5 second opening, 3.6 top surface, 4 USB pins, and 5 SD card pins.

### DETAILED DESCRIPTION

To illustrate the objectives, technical solutions and advantages of the present invention more clearly, the following further describes the embodiments of the present invention in detail with reference to the accompanying drawings.

An embodiment of the present invention employs a product having a USB connector and an SD card connector integrated as an example for illustration, but not limited thereto, and such a structure is applicable to all connector products each of which has a USB connector and a smart card connector.

### Embodiment 1

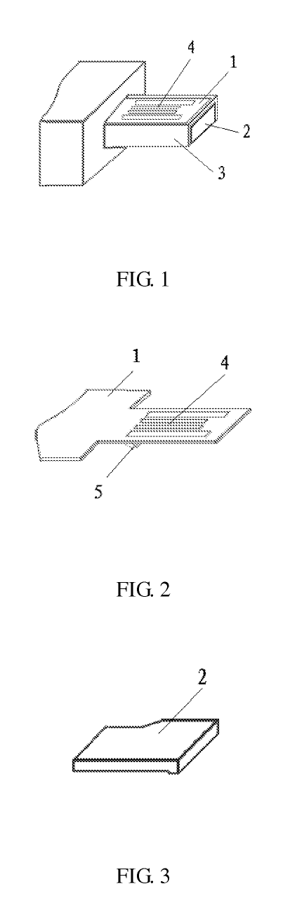

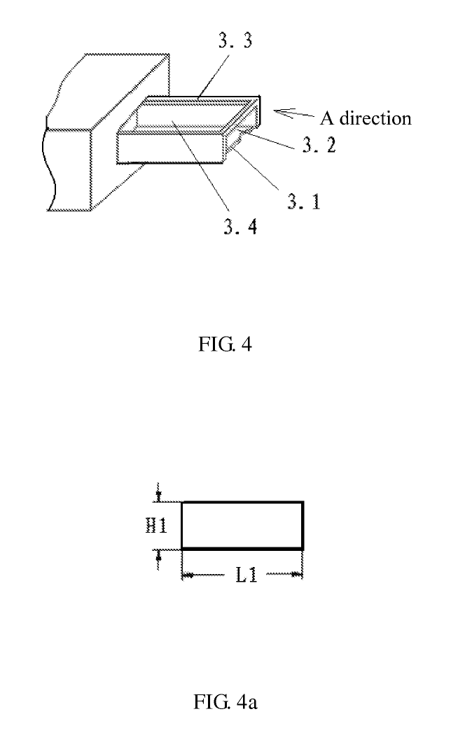

As shown in FIG. 1, Embodiment 1 of the present invention provides a connector that includes a PCB 1. One surface of the PCB 1 is disposed with USB pins 4 (shown in FIG. 2), and the other surface is disposed with smart card pins. In this embodiment, the smart card pins are SD card pins 5 (shown in FIG. 2). Of course, persons of ordinary skill in the art may understand that, the smart card pins may be any smart card pins, such as SIM card pins, and may not be limited to the SD card pins. A frame 3 is disposed outside the PCB 1. The frame 3 is configured to bear the PCB 1, the frame 3 and the USB pins 4 form a USB connector, the frame 3 and the PCB surface with the smart card pins form a cavity 3.4 (shown in FIG. 4), and a smart card is inserted into the cavity 3.4 (shown in FIG. 4), so as to form a smart card connector. In this embodiment, the smart card pins are SD card pins 5, so that the inserted smart card is an SD card 2, and the formed smart card connector is an SD card connector. Of course, persons of ordinary skill in the art may understand that the smart card may be any smart card, such as a SIM card, and may not be limited to an SD card.

The embodiment of the present invention utilizes structural parts to form the frame 3 and disposes the USB pins 4 and the SD card pins 5 on upper and lower surfaces of the PCB 1, respectively. The embodiment then inserts the PCB 1 into the structural parts to form a USB interface and inserts the SD card 2 into the cavity 3.4 to form the SD card connector. Therefore, with the embodiment of the present invention, the USB connector is spatially integrated with the SD card connector, so no extra space is occupied; moreover, an overall structure is simple, it is convenient in repair and maintenance, and a cost is low. As a result, a data card product adopting the present invention may effectively economize its volume; and materials of two card holders may be generally reduced, so the cost of a data card product may be lowered.

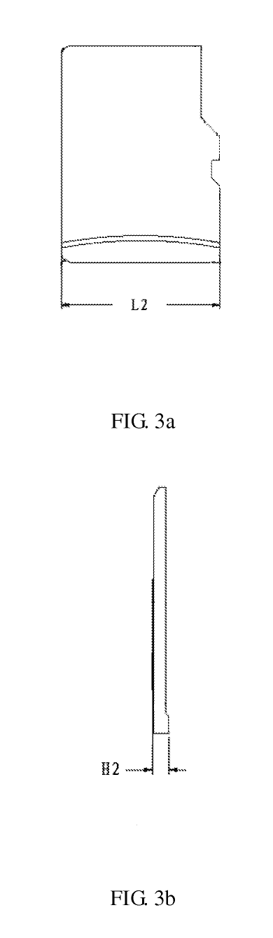

Specifically, the SD card 2 is preferentially a micro SD card (shown in FIG. 3) in this embodiment. As shown in FIG. 3a, the width of the micro SD card is L2=11.0±0.1; and as shown in FIG. 3b, the thickness of the micro SD card is H2=1±0.1. In this embodiment, referring to FIG. 4, the size of the cavity 3.4 in the frame 3 is as shown in FIG. 4a, where the length is L1=12.5±0.1, and the height is H1=2.7±0.1. Referring to FIG. 3a and FIG. 3b, when the maximum size L2×H2 of the micro SD card is 11.1×1.1, and the minimum size L1×H1 (shown in FIG. 4a) of the cavity 3.4 (shown in FIG. 4) is 12.4×2.6, so the cavity 3.4 (shown in FIG. 4a) still has enough space to accommodate the micro SD card.

Specifically, in this embodiment, referring to FIG. 2, the upper surface of the PCB 1 is disposed with the USB pins 4, and the lower surface of the PCB 1 is disposed with the smart card pins which are the SD card pins 5 in this embodiment. Of course, persons of ordinary skill in the art may learn that, the lower surface of the PCB 1 may further be disposed with the USB pins 4, and the upper surface of the PCB 1 may be disposed with the smart card pins which are the SD card pins 5 in this embodiment.

Specifically, in this embodiment, referring to FIG. 4, the frame is a half-head frame. The half-head frame includes a rectangular framework, two sidewalls 3.3 and a bottom surface 3.1 disposed on the framework. One end of the half-head frame is disposed with a first opening 3.2, the half-head frame has the cavity 3.4, and the cavity 3.4 is configured to accommodate the SD card 2 (shown in FIG. 3).

### Embodiment 2

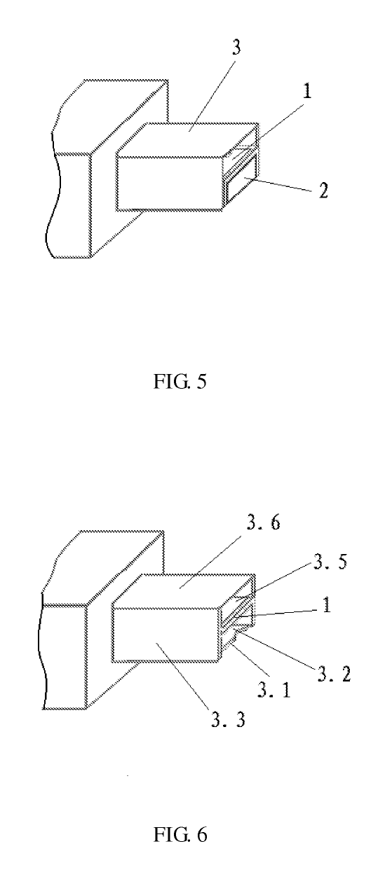

As shown in FIG. 5, Embodiment 2 of the present invention provides a connector; the difference between Embodiment 2 and Embodiment 1 is that the frame in Embodiment 2 is a full-head frame.

Specifically, referring to FIG. 6, the full-head frame includes a rectangular framework, two sidewalls 3.3, a bottom surface 3.1 and a top surface 3.6 disposed on the framework. The PCB 1 is inserted into the full-head frame. The PCB 1 divides the internal cavity of the frame into two cavities, and the two cavities correspond to a first opening 3.2 and a second opening 3.5, respectively. The cavity corresponding to the first opening 3.2 is configured to accommodate an SD card (shown in FIG. 3). The full-head frame and the USB pins 4 (shown in FIG. 2) form a standard USB connector. Of course, persons of ordinary skill in the art may understand that, the smart card pins may be any smart card pins, such as SIM card pins, and may not be limited to the SD card pins; a smart card may be any smart card, such as a SIM card, and may not be limited to an SD card.

### Embodiment 3

Referring to FIG. 1, Embodiment 3 of the present invention provides a wireless modem that includes a connector. The connector includes a PCB 1. One surface of the PCB 1 is disposed with USB pins 4 (shown in FIGS. 1 and 2), the other surface is disposed with smart card pins; in this embodiment, the smart card pins are SD card pins 5 (shown in FIG. 2). Of course, persons of ordinary skill in the art may understand that, the smart card pins may be any smart card pins, such as SIM card pins, and may not be limited to the SD card pins. A frame 3 is disposed outside the PCB 1. The frame 3 is configured to bear the PCB 1. The frame 3 and the USB pins 4 form a USB connector. The frame 3 and the PCB surface with the smart card pins form a cavity 3.4 (shown in FIG. 4), and a smart card is inserted into the cavity 3.4 (shown in FIG. 4), so as to form a smart card connector. In this embodiment, the smart card pins are the SD card pins 5, so that the inserted smart card is an SD card 2, and the formed smart card connector is an SD card connector. Of course, persons of ordinary skill in the art may understand that, the smart card may be any smart card, such as a SIM card, and may not be limited to an SD card.

The embodiment of the present invention utilizes structural parts to form the frame 3 and disposes the USB pins 4 and the SD card pins 5 on upper and lower surfaces of the PCB 1, respectively. The embodiment then inserts the PCB 1 into the structural parts to form a USB interface and inserts the SD card 2 into the cavity 3.4 to form the SD card connector. Therefore, with the embodiment of the present invention, the USB connector is spatially integrated with the SD card connector, so no extra space is occupied; moreover, an overall structure is simple, it is convenient in repair and maintenance, and a cost is low. As a result, a data card product adopting the present invention may effectively economize its volume; and materials of two card holders may be generally reduced, so the cost of a data card product may be lowered.

Specifically, the SD card 2 is preferentially a micro SD card in this embodiment.

Specifically, in this embodiment, referring to FIG. 2, the upper surface of the PCB 1 is disposed with the USB pins 4, and the lower surface of the PCB 1 is disposed with the smart card pins which are the SD card pins 5 in this embodiment. Of course, persons of ordinary skill in the art may learn that, the lower surface of the PCB 1 may further be disposed with the USB pins 4, and the upper surface of the PCB 1 may be disposed with the smart card pins which are the SD card pins 5 in this embodiment.

Specifically, in this embodiment, referring to FIG. 4, the frame is a half-head frame. The half-head frame includes a rectangular framework, two sidewalls 3.3 and a bottom surface 3.1 disposed on the framework. One end of the half-head frame is disposed with a first opening 3.2, the half-head frame has the cavity 3.4, and the cavity 3.4 is configured to accommodate the SD card 2 (shown in FIG. 3).

### Embodiment 4

Referring to FIG. 5, Embodiment 4 of the present invention provides a wireless modem that includes a connector. The difference between this connector and the connector that is in Embodiment 3 is that the frame in Embodiment 4 is a full-head frame.

Specifically, referring to FIG. 6, the full-head frame includes a rectangular framework with two sidewalls 3.3, a bottom surface 3.1 and a top surface 3.6 disposed on the framework. The PCB 1 is inserted into the full-head frame. The PCB 1 divides the internal cavity of the frame into two cavities, and the two cavities correspond to a first opening 3.2 and a second opening 3.5, respectively. The cavity corresponding to the first opening 3.2 is configured to accommodate the SD card (shown in FIG. 3). The full-head frame and the USB pins 4 (shown in FIG. 2) form a standard USB connector. Of course, persons of ordinary skill in the art may understand that, the smart card pins may be any smart card pins, such as SIM card pins, and may not be limited to the SD card pins. Additionally, the smart card may be any smart card, such as a SIM card, and may not be limited to an SD card.

The above descriptions are only about exemplary embodiments of the present invention, and are not intended to limit the present invention. Any modification, equivalent substitution and improvement made within the idea and principle of the present invention should fall within the protection scope of the present invention.

What is claimed is:

1. A connector comprising:
a printed circuit board (PCB); and
a frame,
wherein one surface of the PCB is disposed with USB pins,
wherein another surface of the PCB is disposed with smart card pins,
wherein the frame is disposed outside the PCB,
wherein the frame is configured to bear the PCB,
wherein the frame and the USB pins form a USB connector,
wherein the frame and the another surface of the PCB that is disposed with the smart card pins form a cavity, and
wherein a smart card is inserted into the cavity to form a smart card connector.

2. The connector according to claim 1, wherein the frame is a half-head frame.

3. The connector according to claim 1, wherein the frame is a full-head frame.

4. The connector according to claim 1, wherein an upper surface of the PCB is disposed with the USB pins, and wherein a lower surface of the PCB is disposed with the smart card pins.

5. The connector according to claim 1, wherein a lower surface of the PCB is disposed with the USB pins, and wherein an upper surface of the PCB is disposed with the smart card pins.

6. The connector according to claim 5, wherein the smart card pins are secure digital memory (SD) card pins, and wherein the smart card is a micro SD card.

7. A wireless modem comprising:
a universal serial bus (USB) connector; and
a frame;
wherein the USB connector comprises a printed circuit board (PCB),
wherein one surface of the PCB is disposed with USB pins,
wherein another surface of the PCB is disposed with smart card pins,
wherein the frame is disposed outside the PCB,
wherein the frame is configured to bear the PCB,
wherein the frame and the USB pins form the USB connector,
wherein the frame and the another surface of the PCB that is disposed with the smart card pins form a cavity, and
wherein a smart card is inserted into the cavity to form a smart card connector.

8. The wireless modem according to claim 7, wherein the frame is a half-head frame.

9. The wireless modem according to claim 7, wherein the frame is a full-head frame.

10. The wireless modem according to claim 7, wherein an upper surface or a lower surface of the PCB is disposed with the USB pins, wherein the lower surface or the upper surface of the PCB is disposed with the smart card pins, wherein the smart card pins are SD card pins, and wherein the smart card is a micro SD card.
